(19) United States
(12) Patent Application Publication
(10) Pub. No.: US 2015/0110949 A1
(43) Pub. Date: Apr. 23, 2015

(54) Vacuum In-Situ Thin Layer Color Deposition System and Method

(71) Applicant: Denton Vacuum, L.L.C., Moorestown, NJ (US)

(72) Inventors: David Konopka, Bensalem, PA (US); Richard Wang, Medford, NJ (US); Jules Abiva, Cherry Hill, NJ (US); Rod Moore, Riverton, NJ (US)

(21) Appl. No.: 14/489,818

(22) Filed: Sep. 18, 2014

Related U.S. Application Data
(60) Provisional application No. 61/879,371, filed on Sep. 18, 2013.

(51) Int. Cl. C23C 14/54; C23C 14/34; C23C 14/24

(52) U.S. Cl. CPC C23C 14/54; C23C 14/24; C23C 14/34
USPC 427/8; 118/665; 204/298.03; 204/192.13

(57) ABSTRACT

The system and method of the instant invention utilizes a color sensor in order to monitor and control the application of a coating to a substrate when such coating is transferred onto a substrate from a deposition source. Application of the coating to the substrate is terminated when the color sensor detects a pre-programmed end point evidencing the application of an appropriate coating determined by its color.

### CROSS REFERENCE TO RELATED APPLICATION(S)

This application claims the benefit of U.S. Provisional Application No. 61/879,371, filed Sep. 18, 2013.

### FIELD OF THE INVENTION

The present invention relates in general to vacuum deposition systems and in particular to an in-situ thin layer color deposition system utilizing a color sensor.

### BACKGROUND OF THE INVENTION

The typical vacuum deposition system consists of a vacuum chamber, vacuum valves, vacuum gauges, vacuum pumps, and one or more deposition sources.

The vacuum chamber is typically a welded stainless steel assembly, but can be aluminum. Glass bell jars are also used as vacuum chambers. The chamber size and design are matched to the deposition technology as well as the number of substrates to be coated per cycle.

Vacuum valves are used to safely pump the vacuum chamber down from atmospheric pressure to the required vacuum level.

Vacuum gauges are used to monitor the pressure inside the vacuum chamber, inside the vacuum pumps, and inside the vacuum piping.

A variety of vacuum pumps can be used to remove gas from the vacuum chamber. In general, rough vacuum pumps are used to pump gas from the vacuum chamber from atmospheric pressure to a vacuum pressure level at which it is safe to use a high vacuum pump.

Many types of deposition sources can be used. A deposition source is a device that applies an optical interference filter onto a substrate. Deposition sources can be mounted above or below a substrate. An optical interference filter is the material being applied to a substrate via the deposition source. A substrate is the object to which the optical interference filter (also known as a coating) is applied.

Two main types of deposition sources operate in the manner of evaporation sources. In one evaporation method, a low voltage, high current electrical supply mounted external to the vacuum chamber provides energy to a small resistance source that is mounted inside the vacuum chamber. The resistance source is heated until the evaporation source material on the resistance source evaporates.

In a second evaporation method, an electron beam is focused on a small volume of evaporant source material until the evaporation temperature is reached.

Another common deposition technique that does not rely on evaporation is known as sputtering. In sputtering, a certain amount of gas is re-introduced into the vacuum chamber and a voltage is applied to the face of the deposition source material. The voltage activates a plasma near the surface of the deposition source material. The energetic ions in the plasma collide with the molecules of the deposition source material at its surface and, as a result of these collisions, the deposition source material is deposited onto the substrate in appropriate proximity.

Other deposition techniques, such as atomic layer deposition, are commonly known to those having ordinary skill in the art.

Current methods in depositing a coating require many variables to be characterized and require monitoring, including:
A series of depositions must be made to determine empirically the set of parameters to deposit the optical interference filter at a reliable deposition rate;
Then, a series of depositions must be made to determine the amount of time required to deposit the optical interference filter in the desired color;
Additional tests must be made to characterize the process parameters as the source material is depleted from use;
Very specific variables must them be programmed into the deposition system controller to make the subtle changes required to maintain a consistent color as the chamber conditions change over time;
A deposition recipe is then developed based on the power needed to be applied to the source and the time that the source is needed to be active; and
Any slight deviation in the conditions inside the vacuum chamber can result in subtle changes in the color of the substrate as a result of changes in the film thickness or optical properties.

While prior art systems such as those disclosed in U.S. Pat. No. 6,649,208 to Rodgers and U.S. Pat. No. 7,182,976 to Takahashi employ certain methods to control desired thickness of the deposited coating in a vacuum chamber, a need nonetheless exists to develop a deposition method that is more accurate and uniform than that which exists in the art. Methods such as that described in U.S. Pat. No. 8,182,861 issued to Lee rely in part on optical sensing in order to gauge the thickness of the deposited coating, but methods such as these do not provide the precision needed by certain industries.

### SUMMARY OF THE INVENTION

The invention is based on the use of color sensor technology. The color sensor uses a white light source to determine the color of an object. These sensors convert optical input into a digitized description of color. The color sensor of the instant invention operates as an in-situ device used to measure the color of a coating, such as an optical interference filter, applied to a substrate. The color sensor can be mounted externally on to the vacuum chamber via fiber optic feedthroughs. In addition to the fiber optic leads, specific optical components are required to facilitate the color sensor signal onto and from the area to be measured. Aiming and collimating optical components are used to focus the white light signal onto the area on the substrate of interest and also to collect the reflected signal from such area. The source of the deposited film is some distance away from the substrate that will be coated. The color sensor is mounted such that it is facing some area of the substrate.

As the coating builds up on the substrate or test piece, the color sensor monitors the surface of the substrate or test piece as it exits the deposition area to determine the color of the coating. When the reflected color is identical to the programmed color set point, or, in another embodiment, when the reflected color is within an acceptable range of color set points, the color sensor provides a digital signal to the vacuum deposition control system to end the deposition process.

On receipt of such signal in systems using a shutter to block further deposition, the vacuum deposition shutter closes between the deposition source and the substrate and then ramps down power to the deposition source to end the deposition.

According to the present invention, the foregoing and other objects and advantages are obtained by the use of a color sensor to control the precise point in time at which deposition should be terminated.

### BRIEF DESCRIPTION OF THE DRAWINGS

The invention will become more readily apparent from the following description of preferred embodiments thereof shown, by way of example only, in the accompanying drawings wherein:

FIG. 1 is a cutaway view of a vacuum chamber according to one aspect of the invention.

FIG. 2 is a cutaway view of a vacuum chamber according to another aspect of the invention.

FIG. 3 is a flowchart outlining the steps for using a vacuum chamber according to one aspect of the invention.

### DETAILED DESCRIPTION OF THE INVENTION

The instant invention solves the problem of non-uniform, inaccurate vacuum deposition of certain coatings, such as optical interference filters, on substrates using time-based deposition techniques. The invention is based on the use of color sensor technology. Color sensors are generally used in manufacturing or packaging industries to differentiate products based on color. The color sensor uses a white light source to determine the color of an object. These sensors convert optical input into a digitized description of color. Many industry-accepted methods of describing color can be used for this digitized color description.

In addition to color recognition by description, many color sensors available on the market at this time provide the ability to ‘teach’ a specific color by defining the color description with numeric data input or in some cases simply exposing the color sensor to a specific color while the sensor is in the ‘learn’ mode.

Certain considerations for using color sensors according to the instant invention are required in the design of the vacuum deposition system to facilitate the interface of the color sensor to the area of interest. Specifically, the color sensor of the instant invention operates as an in-situ device used to measure the color of a coating, such as an optical interference filter, applied to a substrate. It is not necessary to install the color sensor inside the vacuum chamber. The color sensor can be mounted externally on to the vacuum chamber while the light and color signals enter and exit the vacuum chamber via fiber optic feedthroughs. In addition to the fiber optic leads, specific optical components are required to facilitate the color sensor signal onto and from the area to be measured. Aiming and collimating optical components are used to focus the white light signal onto the area on the substrate of interest and also to collect the reflected signal from such area.

In any vacuum deposition system, the source of the deposited film is some distance away from the substrate that will be coated. In many cases, the substrate to be coated is rotating so as to improve the uniformity of the deposited film.

The color sensor must be mounted such that is facing some area of the substrate. If a white light source cannot be reflected from the substrate (by reason, for example, of the geometry of a part of the substrate with the result that the light source cannot be reflected directly back to the sensor), then a test sample that is coated along with the substrate must be used to reflect the white light source to the color sensor.

In one embodiment of the instant invention, the fiber optic lead and focusing optics are positioned outside the general area of deposition while the signal from the color sensor is reflected from a test sample (or the substrate) as it exits the immediate deposition area.

As the coating builds up on the substrate or test piece, the color sensor monitors the surface of the substrate or test piece as it exits the deposition area to determine the color of the coating. When the reflected color is identical to the programmed color set point or, in another embodiment, when the reflected color is within an acceptable range of color set points, the color sensor provides a digital signal to the vacuum deposition control system to end the deposition process.

On receipt of such signal, in systems using a shutter to block further deposition, the vacuum deposition shutter closes between the deposition source and the substrate and then ramps down power to the deposition source to end the deposition.

By way of illustration, the instant invention may be used to deposit an optical interference filter on a particular item in a medical repair kit. In order to identify the various components in a medical repair kit, a vacuum deposited optical interference filter is applied to the components. The optical inference coating provides selective reflection at specific wavelengths. That selective reflection results in a distinctive color on the individual component.

In this case, the coating material (the material used to deposit the vacuum deposited optical interference filter) used to apply the color must be an accepted bio-compatible material. The method of application of the optical inference filter in this case is sputtering. But, the instant invention can be utilized with other deposition methods known to those having ordinary skill in the art.

But, in any case, as the vacuum deposited optical interference filter is applied, the color sensor will trigger only at the time when the sample color matches the programmed color set point.

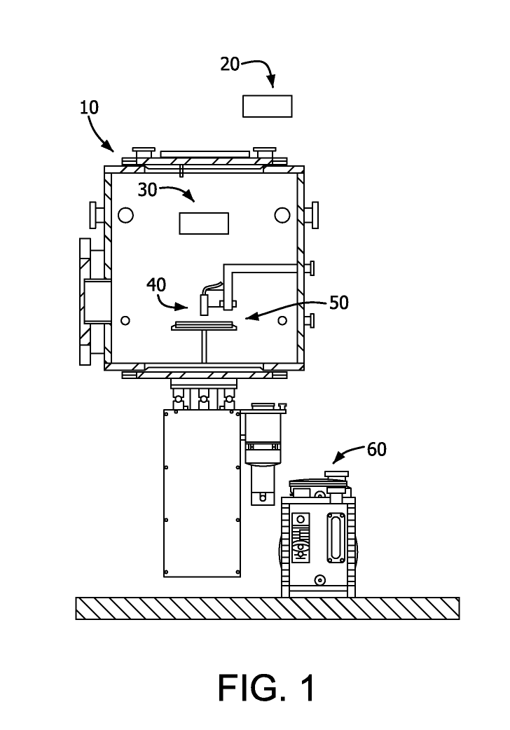

Referring to the drawings wherein like or similar references indicate like or similar elements throughout the several views, there is shown in FIG. 1 a vacuum chamber generally identified by reference numeral 10. In this embodiment of the invention, a vacuum deposition control interface 20 is positioned at a point outside the vacuum chamber 10. The control interface 20 is a controller which samples the feedback from a color sensor 40 and halts the deposition process once a desired color is achieved, as such process is further explained in the preceding paragraphs. FIG. 1 also depicts deposition source 30 which is positioned above color sensor 40. Substrate 50 is depicted beneath color sensor 40. But, in other embodiments, a deposition source 30 is positioned below substrate 50. Vacuum pump 60 is depicted on the exterior of the vacuum chamber 10.

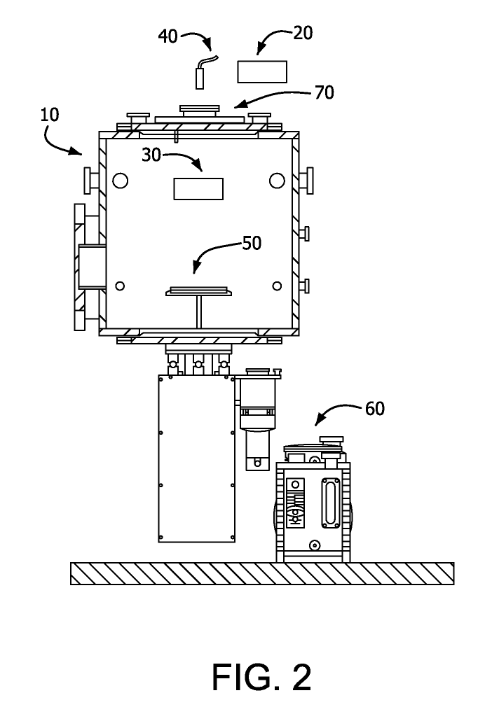

FIG. 2 depicts an alternative embodiment of vacuum chamber 10. In this embodiment, color sensor 40 is situated outside of vacuum chamber 10. As described herein, the color sensor 40 is situated so as to receive color data from the interior of vacuum chamber 10 through a transparent viewport 70 with fiber optics (not depicted).

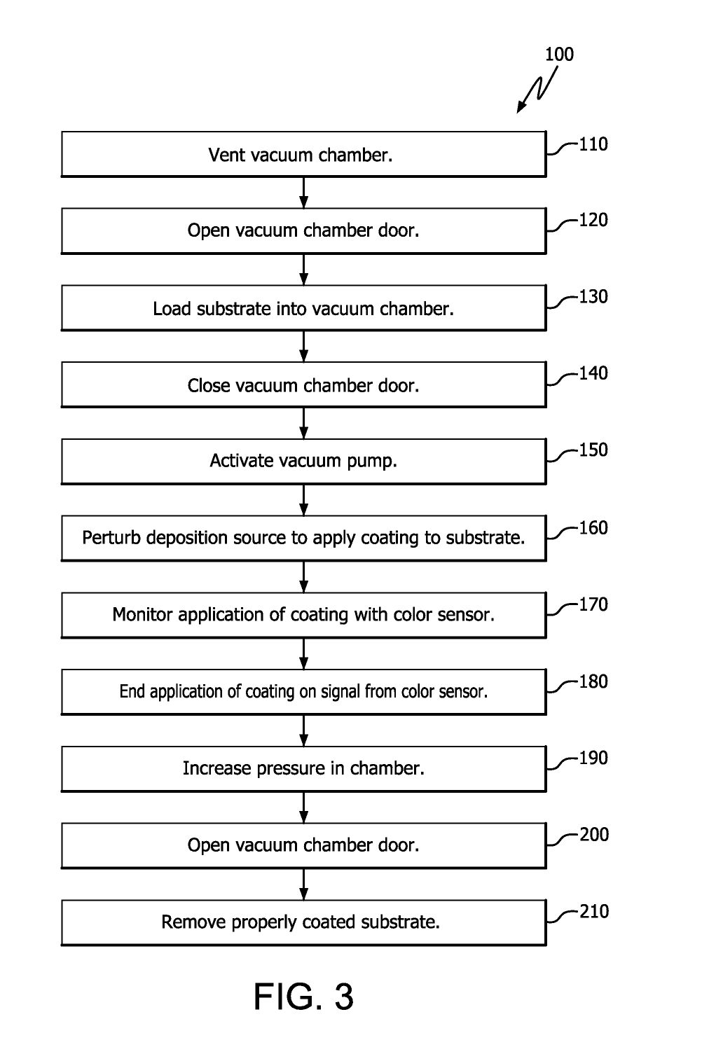

FIG. 3 depicts a schematic, generally identified by reference numeral 100, illustrating the steps of operating the vacuum chamber according to one embodiment of the instant invention. At step 110, the vacuum chamber is vented to atmospheric pressure to allow the loading of a substrate onto the substrate holder. At step 120, the vacuum chamber door is opened, allowing access to the vacuum chamber. At step 130, the substrate is loaded into the chamber. In one embodiment, this is accomplished via a load lock, but it may be accomplished manually in another embodiment. At step 140, the vacuum chamber door is closed, allowing the vacuum chamber's interior cavity to be pumped down to the desired pressure once the vacuum pump is activated at step 150. At step 160, the deposition source applies a coating, such as an optical interference filter or other coating known to those having ordinary skill in the art, onto the substrate. During this application, the color sensor initiates in-situ color evaluation monitoring at step 170. At step 180, the color sensor detects a color sampling matching the desired color and the deposition process ends, thereby permitting the vacuum chamber to be vented to atmospheric pressure which allows the substrate to be unloaded. It is understood that the color sensor is pre-programmed to detect a given color based on a sample that is previously used to set the correct color end point according to the process disclosed herein and as known to those having ordinary skill in this particular art. Alternatively, the color sensor can be pre-programmed to detect whether the reflected color is within an acceptable range of color set points.

What is claimed is:

1. A vacuum deposition system comprising:
a vacuum chamber;
a vacuum pump;
a deposition source for providing a coating;
a color sensor;
a substrate; and
a controller for receiving and monitoring a signal output from said color sensor relative to the coating deposited on said substrate, the output of which controller being connected to said deposition source whereby said deposition is terminated on receipt of a signal of termination from said controller.

2. The vacuum deposition system of claim 1 wherein the deposition source is an evaporation source.

3. The vacuum deposition system of claim 1 wherein the deposition source is a sputtering source.

4. A vacuum deposition system of claim 1 wherein the signal of termination for said controller is based on the color sensed by the color sensor being identical to the programmed color set point.

5. A vacuum deposition system of claim 1 wherein the signal of termination from said controller is based on the color sensed by the color sensor being within an acceptable range of programmed color set points.

6. The vacuum deposition system of claim 2 wherein the color sensor is external to the vacuum chamber and the color sensor is connected to the interior of the vacuum chamber with fiber optic cables permitting light to be transmitted both in and out of the vacuum chamber via fiber optics operatively connected to the color sensor.

7. The vacuum deposition system of claim 3 wherein the color sensor is external to the vacuum chamber and the color sensor is connected to the interior of the vacuum chamber with fiber optic cables permitting light to be transmitted both in and out of the vacuum chamber via fiber optics operatively connected to the color sensor.

8. The vacuum deposition system of claim 1 wherein the deposition source is above the substrate in the vacuum chamber.

9. The vacuum deposition system of claim 1 wherein the deposition source is below the substrate in the vacuum chamber.

10. The vacuum deposition system of claim 1 wherein said coating is an optical interference filter.

11. A method for using a color sensor for in-situ characterization and end point detection of a vacuum deposited coating comprising the steps of:
defining a color description end point for a finished coating on a substrate;
applying a coating to the substrate during vacuum deposition in an evacuated vacuum chamber;
monitoring by a color sensor the surface of the substrate in order to determine the color of the coating; and
ending the coating application at the point in time that reflected color from the surface of the substrate is identical to the defined color description end point as determined by the color sensor measurements.

12. The method of claim 11 wherein the step of defining a color description end point for a finished coating on a substrate comprises programming the color sensor with a numeric data value representing the color description end point.

13. The method of claim 11 wherein the step of defining a color description end point for a finished coating on a substrate comprises programming the color sensor by exposing the color sensor to a sample having the color description end point whereby the color sensor stores data representing the exhibited color as the color description end point.

14. The method of claim 11 further comprising the steps of:
aiming and collimating the color sensor in order to focus a white light signal onto the substrate; and
collecting the reflected light from the substrate.

15. The method of claim 11 further comprising the steps of:
coating a test sample with a coating simultaneously with the substrate;
aiming and collimating the color sensor in order to focus a white light signal onto the test sample; and
collecting the reflected light from the test sample.

16. The method of claim 11 wherein the coating is an optical interference filter.

17. The method of claim 11 wherein the color sensor is positioned inside the vacuum chamber.

18. The method of claim 11 wherein the color sensor is positioned external to the vacuum chamber and light is transmitted both in and out of the vacuum chamber via fiber optics operatively connected to the color sensor.

19. A method for using a color sensor for in-situ characterization and end point detection of a vacuum deposited coating comprising the steps of:
defining a range of acceptable color set points for a finished coating on a substrate;
applying a coating to the substrate during vacuum deposition in an evacuated vacuum chamber;
monitoring by a color sensor the surface of the substrate in order to determine the color of the coating; and
ending the coating application at the point in time that reflected color from the surface of the substrate is within the range of acceptable color set points as determined by the color sensor measurements.

20. The method of claim 19 wherein the step of defining a range of acceptable color set points for a finished coating on a substrate comprises programming the color sensor by exposing the color sensor to a sample having the color description end point whereby the color sensor stores data representing the exhibited color as the color description end point.

21. The method of claim 19 further comprising the steps of:
aiming and collimating the color sensor in order to focus a white light signal onto the substrate; and
collecting the reflected light from the substrate.

22. The method of claim 19 further comprising the steps of:
coating a test sample with a coating simultaneously with the substrate;
aiming and collimating the color sensor in order to focus a white light signal onto the test sample; and
collecting the reflected light from the test sample.

23. The method of claim 19 wherein the coating is an optical interference filter.

24. The method of claim 19 wherein the color sensor is positioned inside the vacuum chamber.

25. The method of claim 19 wherein the color sensor is positioned external to the vacuum chamber and light is transmitted both in and out of the vacuum chamber via fiber optics operatively connected to the color sensor.
